(19) United States
(12) Patent Application Publication
(10) Pub. No.: US 2024/0047600 A1
(43) Pub. Date: Feb. 8, 2024

(54) TRANSISTOR FOR IMPLEMENTING PHOTO-RESPONSIVE NEURONAL DEVICE

(71) Applicant: Korea Advanced Institute of Science and Technology, Daejeon (KR)

(72) Inventors: Yang-Kyu CHOI, Daejeon (KR); Joon-Kyu HAN, Daejeon (KR)

(21) Appl. No.: 17/630,463

(22) PCT Filed: Dec. 15, 2021
(86) PCT No.: PCT/KR2021/019067

§ 371 Date: Jun. 23, 2022

(30) Foreign Application Priority Data
Dec. 18, 2020 (KR) 10-2020-0178161
Jun. 21, 2021 (KR) 10-2021-0080089

(51) Int. Cl. H01L 31/113; G06N 3/067

(52) U.S. Cl. CPC H01L 31/1136; G06N 3/067

(57) ABSTRACT

A transistor for implementing a photo-responsive neuronal device is disclosed. According to one example embodiment, the transistor includes a semiconductor substrate including a hole barrier region or an electron barrier region; a floating body extended in a horizontal direction on the hole barrier region or the electron barrier region; a source region and a drain region formed at both ends of the floating body; a gate insulating film formed on the floating body; and a gate region formed on the gate insulating film.

This application claims the priority benefit of Korean Patent Application No. 10-2020-0178161, filed on Dec. 18, 2020, and Korean Patent Application No. 10-2021-0080089, filed on Jun. 21, 2021, in the Korean Intellectual Property Office, the disclosure of each of which is incorporated herein by reference in its entirety.

### BACKGROUND

### 1. Field of the Invention

The following example embodiments relate to a transistor for implementing a photo-responsive neuronal device, and a neuromorphic-based artificial visual perception system including the neuronal device.

### 2. Description of Related Art

As an alternative that may overcome limitations of the existing Von Neumann method consuming a lot of energy in AI operations, a neuromorphic computing system is receiving a lot of attention. The neuromorphic computing is a technology for implementing AI operations by imitating human brain in hardware. The human brain performs very complex functions, but the brain consumes only 20 W of energy. The neuromorphic computing may perform AI operations such as association, inference, recognition, and the like that are superior to the existing computing by imitating the human brain structure itself with ultra-low power.

Such neuromorphic computing is widely used in an artificial visual perception system to enable efficient pattern recognition, object detection, and real-time image processing by imitating a biological visual perception system. In the biological visual perception system, when photoreceptor present in retina receives external light, ganglion cell of the retina may be activated. Accordingly, the ganglion cell may generate electrical spike signals that vary with light intensity, and transmit the signals to visual cortex. Therefore, based on the signals transmitted to the visual cortex, optical image processing begins in a neural network, so it is possible to recognize objects. To imitate such biological visual perception system by using hardware, it requires elements that act as retinal neurons such as the photoreceptor and the ganglion cell. However, since the existing passive photodetector has no such function, it may not be applied.

Instead, a system that an image sensor detecting optical signals, a circuit converting optical signals to electrical signals, and an artificial neural network processing transmitted signals are combined is used. However, such method has high hardware cost, and also, in the process of converting optical signals to electrical signals, bottleneck phenomenon may be caused, and accordingly, signal delay and additional power consumption may occur.

Therefore, there is a need to propose a technology for overcoming the limitations of the existing technology using the image sensor, the optical signal converting circuit, and the processing artificial neural network.

### SUMMARY

The example embodiments propose a transistor for implementing a photo-responsive neuronal device, by changing spiking characteristics when light is incident, and an artificial visual perception system including the neuronal device.

Accordingly, the example embodiments propose a transistor having all of a function for detecting light in a single device and a function for expressing a spike, and an artificial visual perception system including the neuronal device.

However, the technical problems to be solved by the example embodiments are not limited to the above problems, and may be variously expanded in the scope not beyond the technical idea and field of the described examples.

According to one example embodiment, a transistor for implementing photo-responsive neuronal device includes a semiconductor substrate including a hole barrier region or an electron barrier region; a floating body extended in a horizontal direction on the hole barrier region or the electron barrier region; a source region and a drain region formed at both ends of the floating body; a gate insulating film formed on the floating body; and a gate region formed on the gate insulating film.

According to one aspect of at least one example embodiment, the floating body may be configured to accumulate all of hole generated by impact ionization and hole generated by photon incident on the floating body.

According to another aspect of at least one example embodiment, the source region and the drain region may be configured to output voltage signals in a spike form through integration phenomenon and firing phenomenon in response to current signals applied to the source region and the drain region, and increase spiking frequency by lowering firing threshold voltage in response to photon incident.

According to another aspect of at least one example embodiment, the semiconductor substrate may be configured to be formed of at least one of Si, SiGe, Strained Si, Strained SiGe, SOI (Silicon-On-Insulator), SiC or 3-5 group compound semiconductor.

According to another aspect of at least one example embodiment, the hole barrier region or the electron barrier region may be configured to be formed of at least one of Buried oxide, Buried n-well, Buried p-well, Buried SiC or Buried SiGe.

According to another aspect of at least one example embodiment, the floating body may be configured to be formed of at least one of Si, SiGe or 3-5 group compound semiconductor while having at least one structure of a planar type, a fin type, a nanowire type or a nanosheet type

According to another aspect of at least one example embodiment, the semiconductor substrate may be configured to be operable as a back gate.

According to another aspect of at least one example embodiment, the source region and the drain region may be configured to be formed of at least one of p-type silicon, n-type silicon or metal silicide.

According to another aspect of at least one example embodiment, the source region and the drain region formed of the p-type silicon or the n-type silicon may be configured to be formed with at least one method of diffusion, solid-phase diffusion, epitaxial growth, selective epitaxial growth, ion implantation or succeeding thermal treatment.

According to another aspect of at least one example embodiment, the metal silicide may be configured to include at least one of Er, Yb, Sm, Y, Gd, Tb, Ce, Pt, Pb, Ir, Ni, Ti, W, and, Co, and the source region and the drain region formed of the metal silicide may be configured to use dopant segregation for improved junctions.

According to another aspect of at least one example embodiment, the gate insulating film may be configured to be formed of at least one of silicon oxide, silicon nitride, silicon oxynitride, aluminum oxide, hafnium oxide, hafnium oxynitride, zinc oxide, zirconium oxide, polymer dielectric or HZO.

According to another aspect of at least one example embodiment, the gate insulating film may be configured to include a charge storing layer formed of at least one of poly-silicon, amorphous silicon, metal oxide, silicon nitride, silicon oxynitride, silicon nano-crystal or metal oxide nano-crystal.

According to another aspect of at least one example embodiment, the gate region may be configured to be formed of at least one of n-type polysilicon, p-type polysilicon, TiN, TaN, Al, Mo, Mg, Cr, Pd, Pt, Ni, Ti, Au, Ta, W, Ag or Sn.

According to another aspect of at least one example embodiment, the gate region may be configured to be formed of transparent metal materials comprising at least one of ZnO, SnO or TIO to increase photon transmittance to the floating body.

According to one example embodiment, a transistor for implementing photo-responsive neuronal device includes a semiconductor substrate; a source region and a drain region formed on the semiconductor substrate while being spaced apart from each other in a vertical direction; a floating body extended in the vertical direction between the source region and the drain region; a gate region having gate-all-around surrounding entire side surface of the floating body; and a gate insulating film formed between the floating body and the gate region.

According to one aspect of at least one example embodiment, the floating body may be configured to accumulate all of hole generated by impact ionization and hole generated by photon incident on the floating body.

According to another aspect of at least one example embodiment, the source region and the drain region may be configured to output voltage signals in a spike form through integration phenomenon and firing phenomenon in response to current signals applied to the source region and the drain region, and increase spiking frequency by lowering firing threshold voltage in response to photon incident.

According to one example embodiment, a neuromorphic-based artificial visual perception system includes at least one photo-responsive neuronal device implemented with at least one transistor comprising a semiconductor substrate, a source region and a drain region, a floating body, a gate region, and a gate insulating film, the floating body comprised in the at least one transistor may be configured to accumulate all of hole generated by impact ionization and hole generated by photon incident on the floating body, and the source region and the drain region comprised in the at least one transistor may be configured to output voltage signals in a spike form through integration phenomenon and firing phenomenon in response to current signals applied to the source region and the drain region, and increase spiking frequency by lowering firing threshold voltage in response to photon incident.

According to one aspect of at least one example embodiment, the neuromorphic-based artificial visual perception system may be configured to comprise further at least one of at least one synapse device, at least one resistance, at least one condenser or at least one additional transistor.

According to one example embodiment, a transistor for implementing photo-responsive neuronal device may include a semiconductor substrate including a hole barrier region or an electron barrier region; a floating body accumulating all hole generated by photon incident while extending in a horizontal direction on the hole barrier region or the electron barrier region; a source region and a drain region formed at both ends of the floating body; a gate insulating film formed on the floating body; and a gate region formed on the gate insulating film.

The example embodiments may propose a transistor for implementing a photo-responsive neuronal device by changing spiking characteristics when light is incident, and an artificial visual perception system including the neuronal device.

Accordingly, the example embodiments may propose a transistor having all of a function for detecting light in a single device and a function for expressing a spike, and an artificial visual perception system including the neuronal device.

Therefore, the example embodiments do not require additional elements unlike the existing technology using an image sensor, an optical signal converting circuit, and a processing artificial neural network, so that they may encourage an effect of achieving low-cost high integration by consuming small hardware cost, and an effect of removing bottleneck phenomenon such as signal delay and additional power consumption generated in the process of converting optical signals to electrical signals.

The example embodiments are not limited to the above effects, and may be variously expanded in the scope not beyond the technical idea and field of the described examples.

### BRIEF DESCRIPTION OF THE DRAWINGS

These and/or other aspects, features, and advantages of the disclosure will become apparent and more readily appreciated from the following description of embodiments, taken in conjunction with the accompanying drawings of which:

FIG. 1 is a drawing for describing a biological visual perception system including retinal neurons;

FIG. 2A is a perspective view representing a transistor for implementing a photo-responsive neuronal device according to one example embodiment;

FIG. 2B is a cross sectional side view representing A-A′ cross section of the transistor illustrated in FIG. 2A;

FIG. 3A is a perspective view representing a transistor for implementing photo-responsive neuronal device according to another example embodiment;

FIG. 3B is a cross sectional side view representing A-A′ cross section of the transistor illustrated in FIG. 3A;

FIG. 4 is a drawing for describing operation principle of a photo-responsive neuronal device;

FIGS. 5A to 5B are graphs showing electrical measurement results according to actual measured light intensity from the transistor illustrated in FIGS. 3A to 3B;

FIGS. 6A to 6C are graphs showing electrical measurement results according to actual measured light wavelength from the transistor illustrated in FIGS. 3A to 3B;

FIGS. 7A to 7C are graphs showing electrical measurement results according to gate voltage of the transistor illustrated in FIGS. 3A to 3B; and

FIGS. 8A to 8b are graphs showing simulation results of pattern recognition using the transistor illustrated in FIGS. 3A to 3B.

### DETAILED DESCRIPTION

Hereinafter, embodiments according to the inventive concept will be described in detail with reference to the accompanying drawings. However, the present invention is not limited or limited by the embodiments. In addition, same reference numerals on the drawings may refer to same components throughout.

In addition terminologies used herein are defined to appropriately describe the embodiments of the present invention and thus may be changed depending on a user, the intent of an operator, or a custom in the field to which the present invention pertains. Accordingly, the terminologies must be defined based on the following overall description of this specification.

Hereinafter, a photo-responsive neuronal device according to the described example embodiment is based on a transistor. At this time, the transistor for implementing the neuronal device may have a horizontal transistor structure or a vertical transistor structure.

Before describing the example embodiment in detail, to summarize terminologies, in general, a floating body or floating body layer means a transistor channel consisting of three-electrodes (gate, source, and drain), unlike a field transistor channel based on four-electrodes (gate, source, drain, and body). Typically, it may be widely used in a device on SOI (Silicon-On-Insulator) substrate. In this case, a gate existing at the upper part of the channel may control the upper part of the exposed channel or a part of channel potential through very thin gate insulating film. However, since the lower part of the channel is adjacent to buried oxide, it is difficult to control potential of the lower part of the channel due to very thick buried oxide film even though voltage is applied through a back-gate which is an SOI substrate. Therefore, a SOI device may not effectively control the potential of the lower part of the channel, resulting in an undesirable floating body effect.

In a broader concept, a channel such as a nanowire or a nanosheet, etc. may be a floating body since separate voltage may not be applied to the body even to an isolated channel of a GAA (Gate-All-Around) transistor surrounded by a GAA. However, in this case, since the channel potential is well controlled by the gate due to the gate covering the entire surface of the channel and the very thin gate insulating film, the effect of the floating body may be mitigated.

Unlike the horizontal transistor, since the vertical transistor is formed on a bulk-Si substrate, it appears that there will be no floating body seemingly, but it is not in reality. For example, the channel may be isolated by a n+ source region and a n+ drain region arranged in a vertical direction in case of a p-type body, and a p+ source region and p+ drain region vertically arranged in case of a n-type body to form the floating body structure. Here, the superscript ‘+’ means that the doping concentration is very high, about 1020 cm⁻³. Similarly, the channel may be electrically insulated from the bulk-Si substrate by buried Sic or buried SiGe under vertical protrusion to form the floating body. Therefore, hereinafter, both of the horizontal transistor and the vertical transistor may be expressed as having the floating body.

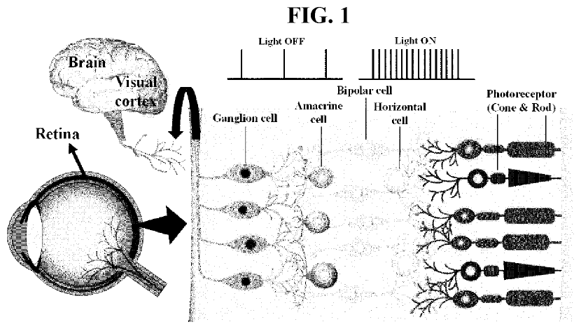

FIG. 1 is a drawing for describing a biological visual perception system including retinal neurons.

Referring to FIG. 1, the human retina may be composed of various neurons such as photoreceptor, bipolar cell, ganglion cell, horizontal cell, amacrine cell, etc. The photoreceptor receives light signals, converts it into electrical signals, and transmits the signals to the ganglion cell through the bipolar cell. The horizontal cell controls reactivity of the photoreceptor to adjust adaptation to the external environment, and the amacrine cell improves sensory perception by making contrast differences through lateral inhibition of the ganglion cell. Visual cortex receiving spike signals from the ganglion cell may recognize an object through signal process in a neural network.

Such biological visual perception system may be imitated as an artificial visual perception system based on a transistor for implementing a photo-responsive neuronal device, which will be described later. A detailed description thereof will be described below.

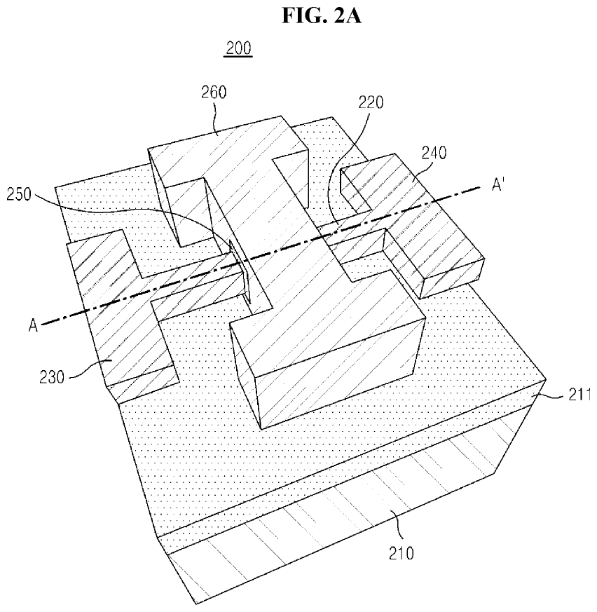

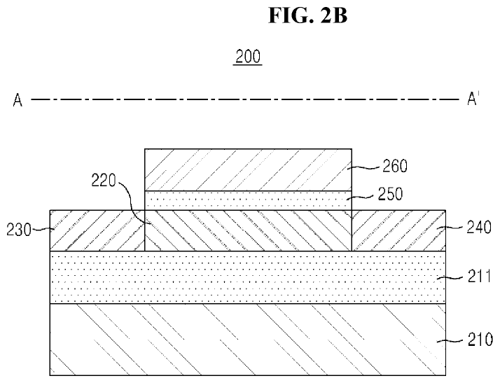

FIG. 2A is a perspective view representing a transistor for implementing a photo-responsive neuronal device according to one example embodiment, and FIG. 2B is a cross sectional side view representing A-A′ cross section of the transistor illustrated in FIG. 2A.

Referring to FIGS. 2A and 2B, a horizontal transistor 200 according to one example embodiment is a device for implementing a photo-responsive neuronal device, so hereinafter, the horizontal transistor 200 may refer to the neuronal device. Also, hereinafter, the horizontal transistor 200 may be referred to as a transistor 200 for convenience.

The transistor 200 may include a semiconductor substrate 210, a floating body 220, a source region 230 and a drain region 240, a gate insulating film 250, and a gate region 260.

The semiconductor substrate 210 may be formed of at least one of Si, SiGe, Strained Si, Strained SiGe, SOI (Silicon-On-Insulator), SiC or 3-5 group compound semiconductor.

Such semiconductor substrate 210 may operate as a back gate applying a voltage bias, and may be configured to include a hole barrier region (or an electron barrier region) 211.

Here, the hole barrier region (or the electron barrier region) 211 may be formed of at least one of Buried oxide, Buried n-well in case of p-type body, Buried p-well in case of n-type body, Buried SiC or Buried SiGe.

The floating body 220 may be formed of at least one of Si, SiGe or −5 group compound semiconductor on the hole barrier region (or the electron barrier region) 211.

Particularly, the floating body 220 may enable a spiking operation of neurons in the transistor 200 by accumulating all of hole generated by impact ionization and hole generated by photon incident on the floating body 220.

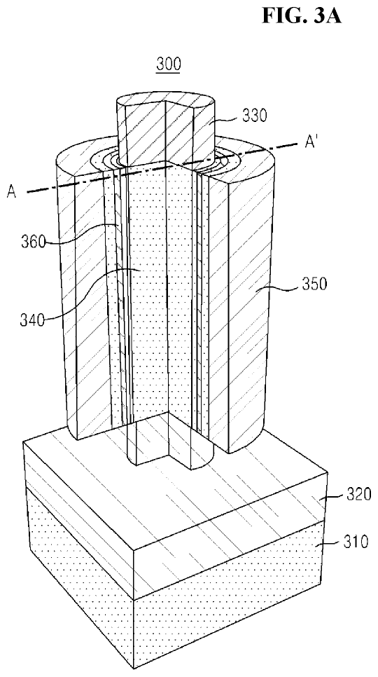

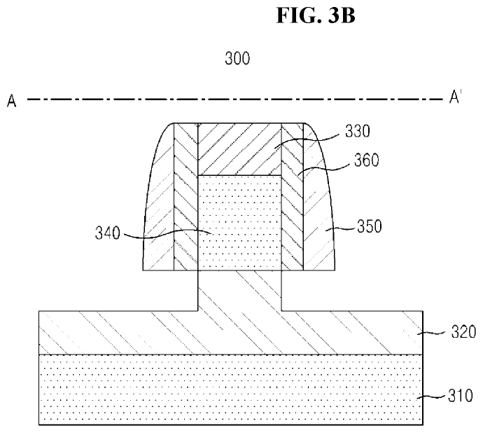

At this time, the floating body 220 may have any one structure of a planar type, a fin type, a nanowire type or a nanosheet type, and it may be formed to extend in a horizontal direction by considering that the transistor 200 is a horizontal transistor. However, it is not limited thereto, and the floating body 220 may be formed to extend in a vertical direction. A detailed description thereof will be described with reference to FIGS. 3A and 3B.

The source region 230 and the drain region 240 may be formed at both ends of the floating body 220 with at least one of p-type silicon, n-type silicon or metal silicide.

For example, the source region 230 and the drain region 240 may be formed of p-type silicon or n-type silicon, and in this case, the source region 230 and the drain region 240 may have a type opposite to the ion type of the floating body 220. As a more specific example, in case that the floating body 220 is p-type, the source region 230 and the drain region 240 may be n-type, and in case that the floating body 220 is n-type, the source region 230 and the drain region 240 may be p-type.

In addition, in case that the source region 230 and the drain region 240 are formed of p-type silicon or n-type silicon, the source region 230 and the drain region 240 may be formed with at least one method of diffusion, solid-phase diffusion, epitaxial growth, selective epitaxial growth, ion implantation or succeeding thermal treatment.

As another example, the source region 230 and the drain region 240 may be formed of metal silicide including at least one of Er, Yb, Sm, Y, Gd, Tb, Ce, Pt, Pb, Ir, Ni, Ti, W, and Co, and in this case, the source region 230 and the drain region 240 formed of metal silicide may use dopant segregation for improved junctions, so the transistor 200 may be a dopant segregation schottky barrier transistor.

Such source region 230 and drain region 240 may output voltage signals in a spike form through integration phenomenon and firing phenomenon in response to current signals applied to the source region 230 and the drain region 240.

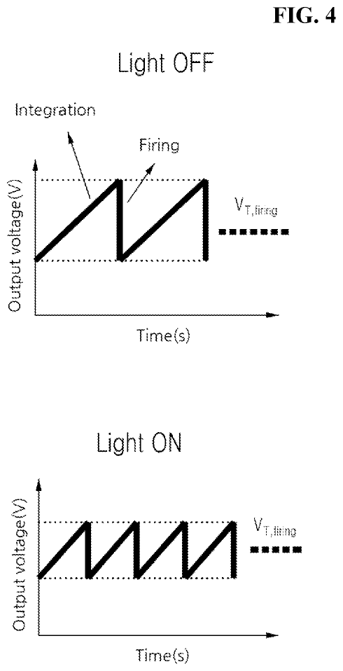

Particularly, the source region 230 and the drain region 240 may increase spiking frequency by lowering firing threshold voltage in the floating body 220 in response to photon incident to the floating body 220. A detailed description thereof will be described with reference to FIG. 4

The gate insulating film 250, as an element insulating the floating body 220 and the gate region 260, may be formed of at least one of silicon oxide, silicon nitride, silicon oxynitride, aluminum oxide, hafnium oxide, hafnium oxynitride, zinc oxide, zirconium oxide, polymer dielectric or HZO on the floating body 220.

Also, the gate insulating film 250 may include a charge storing layer formed of at least one of poly-silicon, amorphous silicon, metal oxide, silicon nitride, silicon oxynitride, silicon nano-crystal or metal oxide nano-crystal.

The gate region 260 may be formed of at least one of n-type polysilicon, p-type polysilicon, TiN, TaN, Al, Mo, Mg, Cr, Pd, Pt, Ni, Ti, Au, Ta, W, Ag or Sn on the gate insulating film 250.

Meanwhile, the gate region 260 may be formed of transparent metal materials including at least one of ZnO, SnO or TIO to increase photon transmittance to the floating body 220.

In addition, the gate region 260 may have at least one structure of a double-gate, a tri-gate, an omega-gate or multiple-gate.

Such gate region 260 and gate insulating film 250 may be not needed when doping concentration of the floating body 220 is greater than or equal to a certain value (e.g., 5*10¹⁷ cm⁻³). In this case, the transistor 200 may have a structure of a two-terminal npn gateless transistor or pnp gateless transistor.

FIG. 3A is a perspective view representing a transistor for implementing photo-responsive neuronal device according to another example embodiment, and FIG. 3B is a cross sectional side view representing A-A′ cross section of the transistor illustrated in FIG. 3A.

Referring to FIGS. 3A and 3B, a vertical transistor 300 according to another example embodiment is a device for implementing a photo-responsive neuronal device, so hereinafter, the vertical transistor 300 may refer to the neuronal device. Also, hereinafter, the vertical transistor 300 may be referred to as a transistor 300 for convenience.

The transistor 300 may include a semiconductor substrate 310, a source region 320 and a drain region 330, a floating body 340, a gate region 350, and a gate insulating film 360.

The semiconductor substrate 310 may be formed of at least one of Si, SiGe, Strained Si, Strained SiGe, SOI (Silicon-On-Insulator), SiC or 3-5 group compound semiconductor.

Such semiconductor substrate 310 may operate as a back gate applying a voltage bias, and may be configured to not include a hole barrier region (or an electron barrier region).

This is because the gate region 350, which will be described later, has a GAA (Gate-All-Around) structure surrounding entire side surface of the floating body 340, so that hole generated by impact ionization or photon incident on the floating body 340 may be trapped without a hole barrier.

The source region 320 and the drain region 330 may be formed of at least one of p-type silicon, n-type silicon or metal silicide while being spaced apart from each other in a vertical direction.

For example, the source region 320 and the drain region 330 may be formed of p-type silicon or n-type silicon, and in this case, the source region 320 and the drain region 330 may have a type opposite to the ion type of the floating body 340. As a more specific example, in case that the floating body 340 is p-type, the source region 320 and the drain region 330 may be n-type, and in case that the floating body 340 is n-type, the source region 320 and the drain region 330 may be p-type.

In addition, in case that the source region 320 and the drain region 330 are formed of p-type silicon or n-type silicon, the source region 320 and the drain region 330 may be formed with at least one method of diffusion, solid-phase diffusion, epitaxial growth, selective epitaxial growth, ion implantation or succeeding thermal treatment.

As another example, the source region 320 and the drain region 330 may be formed of metal silicide including at least one of Er, Yb, Sm, Y, Gd, Tb, Ce, Pt, Pb, Ir, Ni, Ti, W, and Co, and in this case, the source region 320 and the drain region 330 formed of metal silicide may use dopant segregation for improved junctions, so the transistor 300 may be a dopant segregation schottky barrier transistor.

Such source region 320 and drain region 330 may output voltage signals in a spike form through integration phenomenon and firing phenomenon in the floating body 340 in response to current signals applied to the source region 320 and the drain region 330.

Particularly, the source region 320 and the drain region 330 may increase spiking frequency by lowering firing threshold voltage in the floating body 340 in response to photon incident to the floating body 340. A detailed description thereof will be described with reference to FIG. 4.

The floating body 340 may be formed to extend with at least one of Si, SiGe or 3-5 group compound semiconductor between the source region 320 and the drain region 330.

Particularly, the floating body 340 may enable a spiking operation of neurons in the transistor 300 by accumulating all of hole generated by impact ionization and hole generated by photon incident on the floating body 340.

At this time, the floating body 340 may have any one structure of a planar type, a fin type, a nanowire type or a nanosheet type, and it may be formed to extend in a vertical direction by considering that the transistor 300 is a vertical transistor.

The gate region 350 may be formed of at least one of n-type polysilicon, p-type polysilicon, TiN, TaN, Al, Mo, Mg, Cr, Pd, Pt, Ni, Ti, Au, Ta, W, Ag or Sn to have the GAA structure surrounding the entire side surface of the floating body 340.

Meanwhile, the gate region 350 may be formed of transparent metal materials including at least one of ZnO, SnO or TIO to increase photon transmittance to the floating body 340.

In addition, the gate region 350 may have at least one structure of a double-gate, a tri-gate, an omega-gate or multiple-gate.

The gate insulating film 360, as an element insulating the floating body 340 and the gate region 350, may be formed of at least one of silicon oxide, silicon nitride, silicon oxynitride, aluminum oxide, hafnium oxide, hafnium oxynitride, zinc oxide, zirconium oxide, polymer dielectric or HZO between the floating body 340 and the gate region 350.

Also, the gate insulating film 360 may include a charge storing layer formed of at least one of poly-silicon, amorphous silicon, metal oxide, silicon nitride, silicon oxynitride, silicon nano-crystal or metal oxide nano-crystal.

Such gate region 350 and gate insulating film 360 may be not needed when doping concentration of the floating body 340 is greater than or equal to a certain value (e.g., 5*10¹⁷ cm⁻³). In this case, the transistor 300 may have a structure of a two-terminal npn gateless transistor or pnp gateless transistor.

The horizontal transistor 200 and the vertical transistor 300 described above may be included in a neuromorphic-based artificial visual perception system, so that the artificial visual perception system may imitate a biological visual perception system. In this case, the artificial visual perception system is not limited to including at least one of the above described horizontal transistor 200 or vertical transistor 300, and it may include further at least one of at least one synapse device, at least one resistance, at least one condenser or at least one additional transistor (another transistor distinct from the horizontal transistor 200 or the vertical transistor 300).

FIG. 4 is a drawing for describing operation principle of a photo-responsive neuronal device.

Referring to FIG. 4, in the transistor for implementing the photo-responsive neuronal device described with reference to FIGS. 2A and 2B or 3A and 3B, when current signals are applied to a source region or a drain region, integration phenomenon in which charges are accumulated may occur. After this, when the accumulated charges are greater than or equal to a certain value (a value based on firing threshold voltage VT, firing), firing phenomenon in which the accumulated charges discharged may occur. Due to repetition of the integration phenomenon and the firing phenomenon, the transistor outputs voltage signals in a spike form.

Here, the principle that the accumulated charges are discharged in an instant is based on single transistor latch phenomenon. More particularly, it is a phenomenon in which hole generated by impact ionization generated by high voltage in the source region and the drain region is accumulated over a certain level and a large current flows rapidly.

At this time, when additional hole is generated by photon in addition to impact ionization, the firing threshold voltage VT, firing is decreased, so that spiking may be active as spiking frequency is increased.

Therefore, characteristics of biological retinal neurons in which spiking frequency is increased in response to photon which is light may be imitated through the transistor.

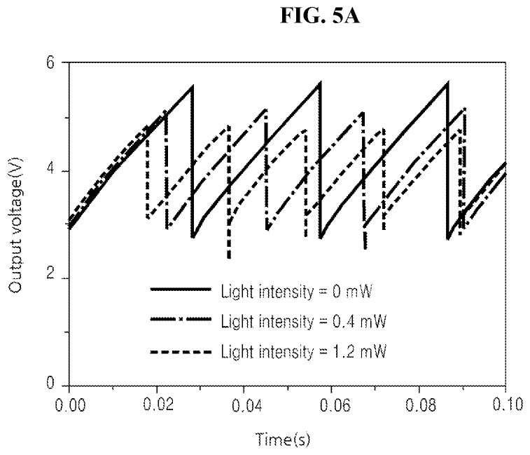

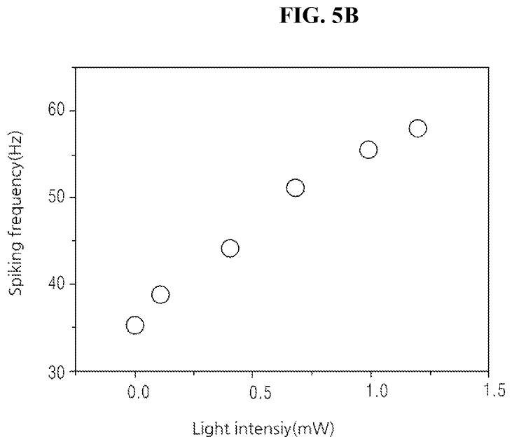

FIGS. 5A to 5B are graphs showing electrical measurement results according to actual measured light intensity from the transistor illustrated in FIGS. 3A to 3B. Hereinafter, electrical measurement results of a vertical transistor will be described, but electrical measurement results of a horizontal transistor may also appear the same.

Referring to FIG. 5A, it may be seen that when constant current signals are input to the transistor, voltage in a spike form is output. At this time, it may be seen that when light is irradiated, spiking becomes active as firing threshold voltage decreases. The reason is that additional hole is generated by photon, which may cause firing at lower voltage.

Referring to FIG. 5B, it may be seen that spiking frequency increases as light intensity increases.

The experiments of FIGS. 5A and 5B were directly measured in a vertical transistor (neuronal device) having a vertical nanowire diameter of 700 nm, and gate voltage of −1V and drain constant current of 100 nA were applied to enable neuron operations. In addition, LED white light was used as a light source.

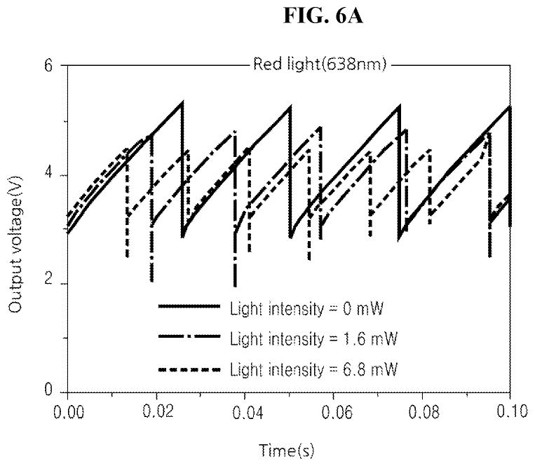

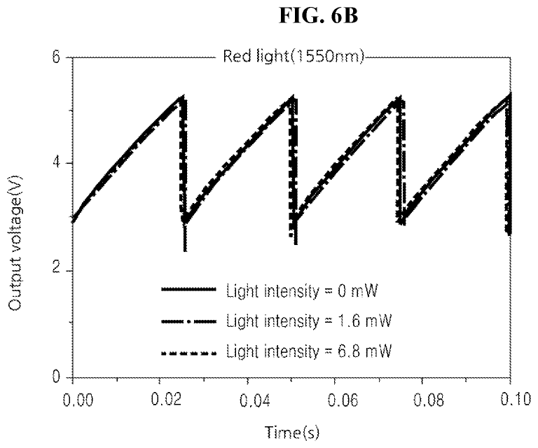

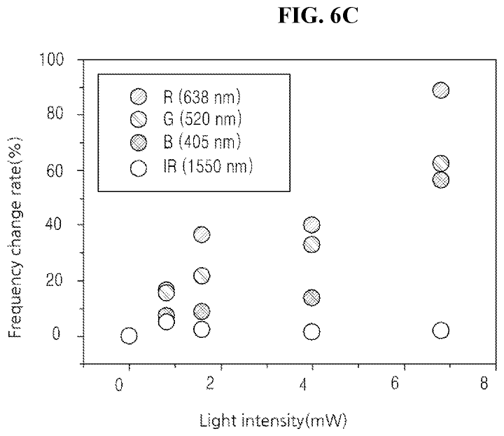

FIGS. 6A to 6C are graphs showing electrical measurement results according to actual measured light wavelength from the transistor illustrated in FIGS. 3A to 3B. Hereinafter, electrical measurement results of a vertical transistor will be described, but electrical measurement results of a horizontal transistor may also appear the same.

Referring to FIG. 6A, it may be seen that when red light R with a wavelength of 638 nm is irradiated to the transistor, spiking becomes active as firing threshold voltage decreases. However, referring to FIG. 6b, it may be seen that when infrared rays (IR) having a wavelength of 1550 nm is irradiated, there is no change in the firing threshold voltage and the spiking frequency.

The reason is that, in case of infrared rays, since energy is smaller than energy band gap 1.12 eV of silicon, hole may not be generated.

Meanwhile, referring to FIG. 6C, it may be seen that the spiking frequency change is the smallest in blue light among red light R, green light G, and blue light B. The reason is that as the wavelength decreases, energy loss increases and penetration depth decreases.

The experiments of FIGS. 6A to 6C also were directly measured in a vertical transistor (neuronal device) having a vertical nanowire diameter of 700 nm, and gate voltage of −1V and drain constant current of 100 nA were applied to enable neuron operations. In addition, a diode for irradiating a laser and light in a specific wavelength band was used as a light source.

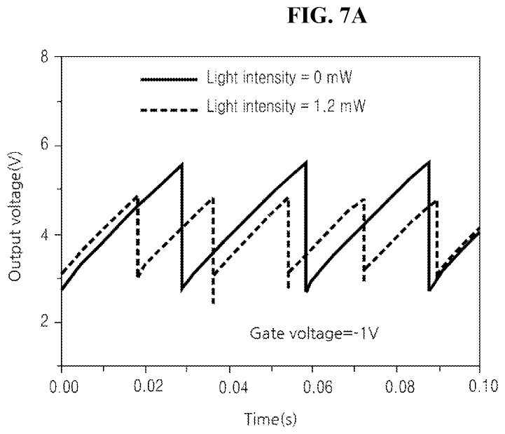

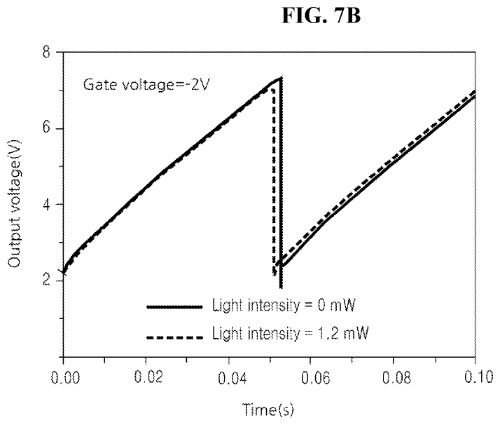

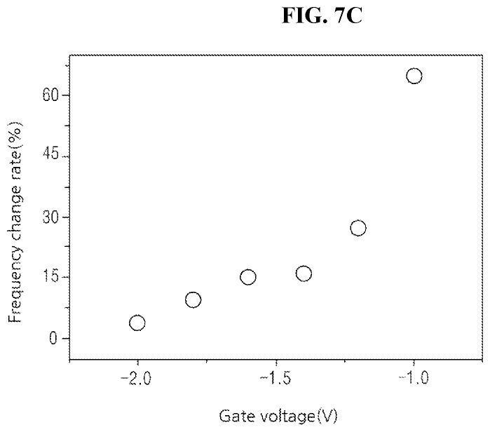

FIGS. 7A to 7C are graphs showing electrical measurement results according to gate voltage of the transistor illustrated in FIGS. 3A to 3B. Hereinafter, electrical measurement results of a vertical transistor will be described, but electrical measurement results of a horizontal transistor may also appear the same.

The reactivity of biological retinal neurons to light is affected by external environment. For example, if eyes are continuously exposed to bright environment, the reactivity decreases, and if eyes are continuously exposed to dark environment, the reactivity increases. Since such characteristic helps retinal neurons to adapt to changing external environment, a neuronal device implemented as a transistor also needs a function to adjust the reactivity of the neuronal device. This may be implemented through adjustment of gate voltage.

As shown in FIG. 7A, when the gate voltage is −1V, the firing threshold voltage and the spiking frequency significantly change as light is irradiated, but it may be seen that when the gate voltage is −2V, there is little change as shown in FIG. 7B. Accordingly, as shown in FIG. 7C, it may be seen that as the gate voltage increases, the change in the spiking frequency increases.

The reason is that when the gate voltage is low, the difference in energy barrier between the source region or the drain region and the floating body is large, and even if additional hole is generated by photon, the effect is small.

The experiments of FIGS. 7A to 7C also were directly measured in a vertical transistor (neuronal device) having a vertical nanowire diameter of 700 nm, and drain constant current of 100 nA was applied to enable neuron operations. In addition, LED white light was used as a light source.

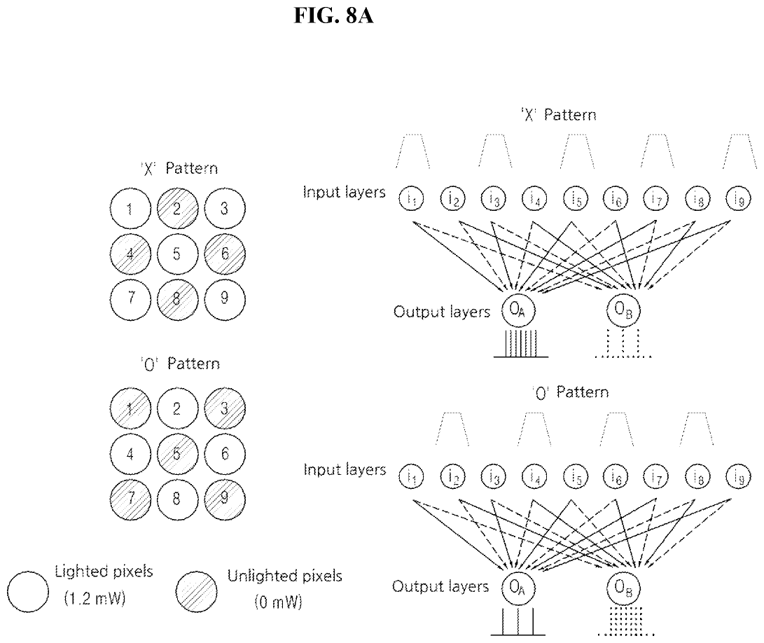

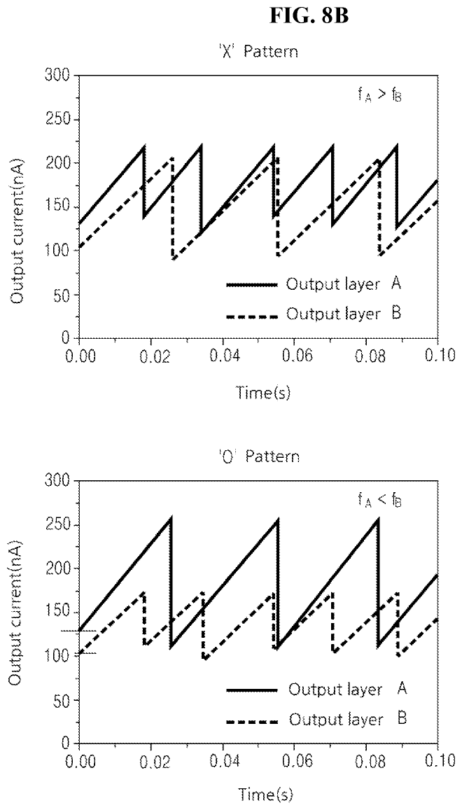

FIGS. 8A to 8b are graphs showing simulation results of pattern recognition using the transistor illustrated in FIGS. 3A to 3B. Hereinafter, simulation results using a vertical transistor will be described, but simulation results using a horizontal transistor may also appear the same.

Referring to FIG. 8A, a neural network was organized to identify ‘X’ pattern and ‘O’ pattern in an image pattern composed of 3*3 black and white pixels. The neural network organized with 9 input layers 1 to 9 and 9*2 output layers A, B. Each pixel represents one input neuron, and white pixels represent lighted pixels and black pixels represent unlighted pixels. The spiking characteristics of the neuronal device that did not receive light and the spiking characteristics of the neuronal device that received 1.2 mW white light were modeled by using SPICE circuit simulation, and since synapse may be imitated as effective resistance, it was expressed as two-terminal resistance.

Referring to FIG. 8B, when comparing the sum of currents output from synapses connected to each output layer, it may be seen that in case that ‘X’ pattern is input, the spiking frequency of current output from the synapses connected to the output layer A is higher, and in case of ‘0’ pattern is input, the spiking frequency of current output from synapses connected to the output layer B is higher. Therefore, image pattern recognition may be performed by using the proposed photo-responsive neuronal device, and since an artificial visual perception system may be configured without an image sensor and a conversion circuit, the artificial visual perception system may be configured with low hardware cost as well as bottleneck phenomenon such as signal delay, additional power consumption, and the like generated in the process of converting optical signals to electrical signals may be removed. Accordingly the neuronal device implemented by the described transistor may configure a high-integrated visual artificial visual perception system with low cost, and enable mass production.

As described above, although the embodiments have been described in connection with the limited embodiments and the drawings, those skilled in the art may modify and change the embodiments in various ways from the description. For example, proper results may be achieved although the aforementioned descriptions are performed in order different from that of the described method and/or the aforementioned elements, such as the system, configuration, device, and circuit, are coupled or combined in a form different from that of the described method or replaced or substituted with other elements or equivalents.

Accordingly, other implementations, other embodiments, and the equivalents of the claims fall within the scope of the claims.

1. A transistor for implementing photo-responsive neuronal device, comprising:
a semiconductor substrate including a hole barrier region or an electron barrier region;
a floating body extended in a horizontal direction on the hole barrier region or the electron barrier region;
a source region and a drain region formed at both ends of the floating body;
a gate insulating film formed on the floating body; and
a gate region formed on the gate insulating film.

2. The transistor of claim 1, wherein the floating body is configured to accumulate all of hole generated by impact ionization and hole generated by photon incident on the floating body.

3. The transistor of claim 2, wherein the source region and the drain region are configured to output voltage signals in a spike form through integration phenomenon and firing phenomenon in response to current signals applied to the source region and the drain region, and increase spiking frequency by lowering firing threshold voltage in response to photon incident.

4. The transistor of claim 1, wherein the semiconductor substrate is configured to be formed of at least one of Si, SiGe, Strained Si, Strained SiGe, SOI (Silicon-On-Insulator), SiC or 3-5 group compound semiconductor.

5. The transistor of claim 1, wherein the hole barrier region or the electron barrier region is configured to be formed of at least one of Buried oxide, Buried n-well, Buried p-well, Buried SiC or Buried SiGe.

6. The transistor of claim 1, wherein the floating body is configured to be formed of at least one of Si, SiGe or 3-5 group compound semiconductor while having at least one structure of a planar type, a fin type, a nanowire type or a nanosheet type.

7. The transistor of claim 1, wherein the semiconductor substrate is configured to be operable as a back gate.

8. The transistor of claim 1, wherein the source region and the drain region are configured to be formed of at least one of p-type silicon, n-type silicon or metal silicide.

9. The transistor of claim 8, wherein the source region and the drain region formed of the p-type silicon or the n-type silicon are configured to be formed with at least one method of diffusion, solid-phase diffusion, epitaxial growth, selective epitaxial growth, ion implantation or succeeding thermal treatment.

10. The transistor of claim 8, wherein the metal silicide is configured to comprise at least one of Er, Yb, Sm, Y, Gd, Tb, Ce, Pt, Pb, Ir, Ni, Ti, W, and, Co,
wherein the source region and the drain region formed of the metal silicide are configured to use dopant segregation for improved junctions.

11. The transistor of claim 1, wherein the gate insulating film is configured to be formed of at least one of silicon oxide, silicon nitride, silicon oxynitride, aluminum oxide, hafnium oxide, hafnium oxynitride, zinc oxide, zirconium oxide, polymer dielectric or HZO.

12. The transistor of claim 1, wherein the gate insulating film is configured to comprise a charge storing layer formed of at least one of poly-silicon, amorphous silicon, metal oxide, silicon nitride, silicon oxynitride, silicon nano-crystal or metal oxide nano-crystal.

13. The transistor of claim 1, wherein the gate region is configured to be formed of at least one of n-type polysilicon, p-type polysilicon, TiN, TaN, Al, Mo, Mg, Cr, Pd, Pt, Ni, Ti, Au, Ta, W, Ag or Sn.

14. The transistor of claim 1, wherein the gate region is configured to be formed of transparent metal materials comprising at least one of ZnO, SnO or TIO to increase photon transmittance to the floating body.

15. A transistor for implementing photo-responsive neuronal device, comprising:
a semiconductor substrate;
a source region and a drain region formed on the semiconductor substrate while being spaced apart from each other in a vertical direction;
a floating body extended in the vertical direction between the source region and the drain region;
a gate region having gate-all-around surrounding entire side surface of the floating body; and
a gate insulating film formed between the floating body and the gate region.

16. The transistor of claim 15, wherein the floating body is configured to accumulate all of hole generated by impact ionization and hole generated by photon incident on the floating body.

17. The transistor of claim 16, wherein the source region and the drain region are configured to output voltage signals in a spike form through integration phenomenon and firing phenomenon in response to current signals applied to the source region and the drain region, and increase spiking frequency by lowering firing threshold voltage in response to photon incident.

18. A neuromorphic-based artificial visual perception system, comprising at least one photo-responsive neuronal device implemented with at least one transistor comprising a semiconductor substrate, a source region and a drain region, a floating body, a gate region, and a gate insulating film,
wherein the floating body comprised in the at least one transistor is configured to accumulate all of hole generated by impact ionization and hole generated by photon incident on the floating body, and
wherein the source region and the drain region comprised in the at least one transistor are configured to output voltage signals in a spike form through integration phenomenon and firing phenomenon in response to current signals applied to the source region and the drain region, and increase spiking frequency by lowering firing threshold voltage in response to photon incident.

19. The neuromorphic-based artificial visual perception system of claim 18, wherein the neuromorphic-based artificial visual perception system is configured to comprise further at least one of at least one synapse device, at least one resistance, at least one condenser or at least one additional transistor.

20. A transistor for implementing photo-responsive neuronal device, comprising:
a semiconductor substrate including a hole barrier region or an electron barrier region;
a floating body accumulating all hole generated by photon incident while extending in a horizontal direction on the hole barrier region or the electron barrier region;
a source region and a drain region formed at both ends of the floating body;
a gate insulating film formed on the floating body; and
a gate region formed on the gate insulating film.
